(19) United States
(12) Patent Application Publication
(10) Pub. No.: US 2012/0126854 A1
(43) Pub. Date: May 24, 2012

(54) FREQUENCY REGENERATION CIRCUIT AND FREQUENCY REGENERATION METHOD

(75) Inventor: Kouichi Yamaguchi, Tokyo (JP)

(73) Assignee: NEC CORPORATION, Tokyo (JP)

(21) Appl. No.: 13/388,842

(22) PCT Filed: Aug. 4, 2009
(86) PCT No.: PCT/JP2009/064095

§ 371 Date: Feb. 3, 2012

(51) Int. Cl. H03D 13/00; H03L 7/097; H03K 3/00

(52) U.S. Cl. 327/3; 327/37; 331/34

(57) ABSTRACT

A frequency regeneration circuit according to the present invention compares a width of a single pulse of input data with a time width of a 1/n clock cycle defined by a phase difference of multi-phase clock signals (where n is a natural number) in order to regenerate a frequency that is 1/n of a rate of the input data.

### TECHNICAL FIELD

The present invention relates to a frequency regeneration circuit and a frequency regeneration method used in a high-speed serial communication.

### BACKGROUND ART

Information on the frequency of data being inputted is important in order to receive signals accurately in a receiving circuit for a high-speed serial communication. A related system is provided with a quartz oscillator for supplying information on the frequency to a receiving side. According to an increase of a communication rate, however, an oscillation frequency and an accuracy of the oscillation frequency required in a quartz oscillator increases. As a result, there is a problem that quartz oscillators that meet those requirements are very expensive. In order to solve such a problem, technology of regenerating a frequency within a receiving circuit has attracted much attention.

The following technologies are disclosed as related frequency regeneration technologies: ICCE 1998 Digest of Technical Paper (H. Kikuchi et al., “Gigabit Video Interface: A Fully Serialized Data Transmission System for Digital Moving Pictures,” Consumer Electronics, 1998. ICCE. 1998 Digest of Technical Papers. International Conference on, 1998, pp. 30-32.) (Non-Patent Literature 1) uses a technique of amplifying serial data into an internal digital signal amplitude with use of an analog amplifier circuit and then performing a phase-frequency comparison between an internal clock signal and the amplified serial data with use of a phase-frequency comparator circuit, which is generally used in a PLL (Phase Locked Loop) circuit. Furthermore, IEEE JSSC 2003 (A. Pottbacker, U. Langmann, and H. Schreiber, “A Si bipolar phase and frequency detector IC for clock extraction up to 8 Gb/s,” Solid-State Circuits, IEEE Journal of, vol. 27, 1992, pp. 1747-1751.) (Non-Patent Literature 2) uses a technique of oversampling serial data to obtain a plurality of data pulses and performing an asynchronous operation on those data pulses so as to extract frequency information.

However, the technique of Non-Patent Literature 1 requires signal amplification of serial data and thus suffers from a problem that much electric power is consumed in the analog amplifier circuit. Furthermore, the technique of Non-Patent Literature 2 requires an asynchronous design for the operation of the data pulses and thus suffers from a problem that it has difficulty in design.

### SUMMARY

An exemplary object of the present invention is to provide a frequency regeneration circuit that regenerates a frequency that is 1/n of a rate of serial data (where n is a natural number) without an analog amplifier circuit for amplifying the serial data and without the need for asynchronous circuit design.

According to one aspect of the present invention, there is provided a frequency regeneration circuit that compares a width of a single pulse of input data with a time width of a 1/n clock cycle defined by a phase difference of multi-phase clock signals (where n is a natural number) in order to regenerate a frequency that is 1/n of a rate of the input data.

Furthermore, according to another aspect of the present invention, there is provided a frequency regeneration circuit including: a judgment circuit operable to sample input data with multi-phase clock signals to obtain judgment results; an exclusive-OR circuit operable to compare judgment results that have been sampled with clock signals having adjacent phase differences to each other for thereby outputting phase comparison results; a frequency comparison logic operable to output frequency comparison results in which a logical operation has been performed on the phase comparison results; a charge pump circuit operable to output a control voltage, the frequency comparison results being inputted to the charge pump circuit; and a voltage controlled oscillator controlled by the control voltage so as to output multi-phase clock signals having a frequency that is 1/n of a rate of the input data (where n is a natural number).

Moreover, according to still another aspect of the present invention, there is provided a frequency regeneration method of converting input data into judgment results that have been sampled with multi-phase clock signals each having a certain phase difference; obtaining phase comparison results by an exclusive-OR operation on the judgment results that have been sampled with clock signals having adjacent phase differences; outputting frequency comparison results obtained by performing a logical operation on the phase comparison results; and outputting multi-phase clock signals controlled by the frequency comparison results, the multi-phase clock signals having a frequency that is 1/n of a rate of the input data (where n is a natural number).

According to the present invention, a width of a single pulse of input data is compared with a time width of a 1/n clock cycle defined by a phase difference of multi-phase clock signals (where n is a natural number), so that a clock signal having a frequency that is 1/n of a rate of the input data can be obtained. The present invention is advantageous in that a frequency that is 1/n of a rate of the input data can be regenerated without an analog amplifier circuit for amplifying a waveform of the input data and without the need for asynchronous circuit design.

### BRIEF DESCRIPTION OF THE DRAWINGS

FIG. 1 is a block diagram showing a frequency regeneration circuit according to a first embodiment of the present invention.

FIG. 2 is a timing chart of generating a frequency comparison result (fdn0) in the first embodiment of the present invention.

FIG. 3 is a timing chart of generating a frequency comparison result (fup0) in the first embodiment of the present invention.

FIG. 4 is a block diagram showing a frequency regeneration circuit according to a second embodiment of the present invention.

FIG. 5 is a timing chart of generating a frequency comparison result (fdn0) in the second embodiment of the present invention.

FIG. 6 is a timing chart of generating a frequency comparison result (fup0) in the second embodiment of the present invention.

FIG. 7 is a timing chart showing a frequency comparison operation on phase synchronization in the second embodiment of the present invention.

FIG. 8 shows an example of a VCO control voltage in a case where a frequency was regenerated with use of the second embodiment of the present invention.

FIG. 9 shows an example of a VCO control voltage in a case where a frequency was regenerated with use of the second embodiment of the present invention.

FIG. 10 shows an example of a frequency control gain in the second embodiment of the present invention.

FIG. 11 is a block diagram showing a frequency regeneration circuit according to a third embodiment of the present invention.

FIG. 12 is a timing chart of generating a frequency comparison result (fdn0) in the third embodiment of the present invention.

FIG. 13 is a timing chart of generating a frequency comparison result (fup0) in the third embodiment of the present invention.

### DETAILED DESCRIPTION OF EXEMPLARY EMBODIMENTS

Embodiments of the present invention will be described below with reference to the drawings.

(First Embodiment)

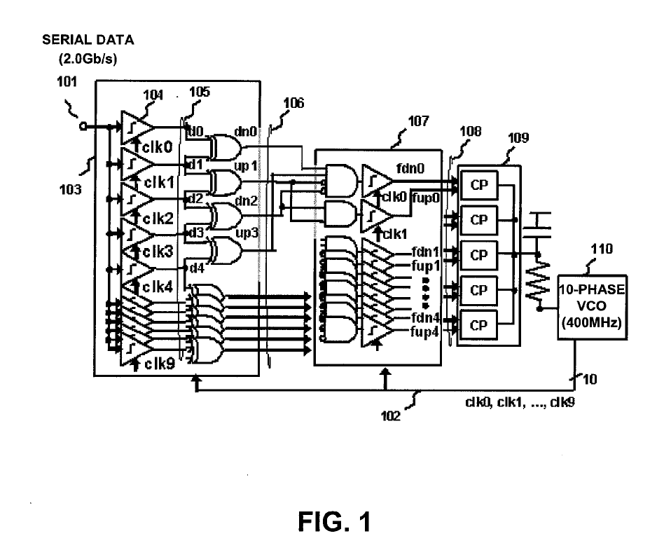

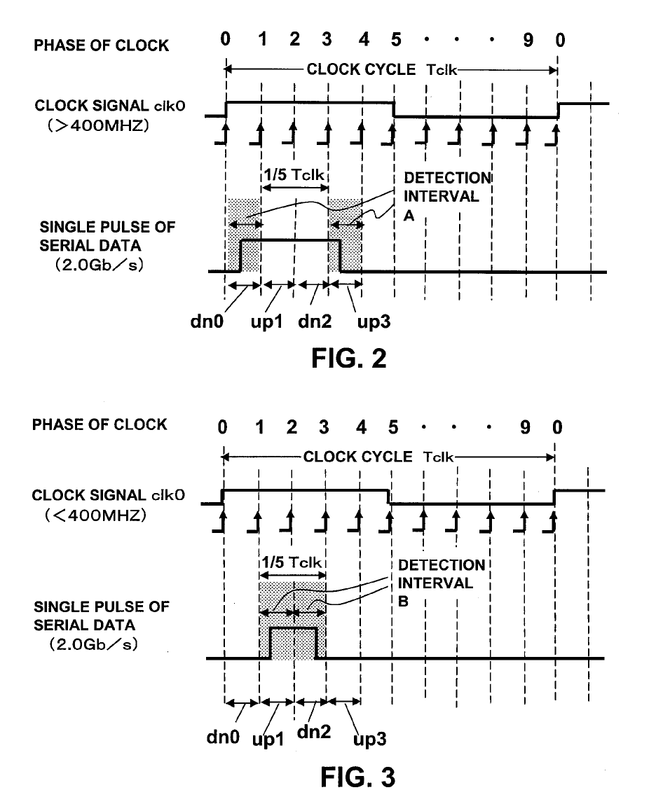

A first embodiment of the present invention will be described with reference to the drawings. FIG. 1 is a block diagram showing a first embodiment of a frequency regeneration circuit according to the present invention. FIG. 2 is a timing chart of generating a frequency comparison result (fdn0) in the first embodiment, and FIG. 3 is a timing chart of generating a frequency comparison result (fup0) in the first embodiment.

The frequency regeneration circuit illustrated in FIG. 1 includes a phase comparator circuit 103, a frequency comparison logic 107, charge pumps 109, and a VCO (Voltage Controlled Oscillator) 110. Serial data 101 of 2.0 Gb/s are oversampled twice with 10-phase clock signals 102, so that a clock signal of 400 MHz, which corresponds to ⅕ of the frequency of the serial data 101, is regenerated. The serial data 101 are first sampled by judgment circuits 104 provided within the phase comparator circuit 103, which operate upon rising edges of the 10-phase clock signals 102 (c1k0-clk9) having equal phase differences. Thus, the serial data 101 are respectively converted into judgment results 105 (d0-d9) as digital data.

Two judgment results 105 sampled with clock signals having adjacent phases are inputted to each of exclusive-OR circuits, which outputs a phase comparison result 106 to the frequency comparison logic 107. For example, judgment results 105 of adjacent phases are inputted to the exclusive-OR (XOR) circuits in the order of d0 and d1, d1 and d2, . . . , d9 and d0. The exclusive-OR circuits output ten phase comparison results 106 of dn0, up1, . . . , up9. As shown in FIG. 1, dn* and up* are alternately outputted as the phase comparison results 106 in the order of adjacent judgment results 105 being inputted. When the serial data 101 make a transition in an interval of adjacent phase differences, the phase comparison result 106 is enabled (so as to have a high level).

The frequency comparison logic 107 performs a logical operation therein with use of the inputted phase comparison results 106 to thereby generate and output frequency comparison results 108. The phase comparison results 106 are inputted to AND circuits, which output frequency comparison results 108 that are synchronized with the clock signals. The frequency comparison logic 107 outputs five pairs of frequency comparison results 108 (fdn0 and fup0), (fdn1 and fup1), . . . , (fdn4 and fup4), which have been generated with the clock signals clk0 and clk1, clk2 and clk3, . . . , clk8 and clk9. The five pairs of frequency comparison results 108 are respectively inputted to the charge pumps 109, which control an oscillation frequency of the VCO 110. The VCO 110 outputs 10-phase clock signals 102 (c1k0-clk9) of 400 MHz that have equal phase differences.

Here, dn* of the phase comparison results 106 and fdn* of the frequency comparison results 108 are down-signals, which slow down the clock signal, whereas up* of the phase comparison results 106 and fup* of the frequency comparison results 108 are up-signals, which accelerate the clock signal. Those definitions differ depending upon what phase of the 10-phase clock signals is used as a reference. According to the present invention, as shown in FIG. 1, down-signals and up-signals are alternately outputted as the phase comparison results 106 and the frequency comparison results 108 in the order of the 10-phase clock signals 102 (c1k0-clk9).

FIGS. 2 and 3 are timing charts explanatory of generation of a frequency comparison result 108. FIG. 2 shows a frequency comparison result 108 (fdn0) for slowing the frequency that is generated when the oscillation frequency of the VCO 110 is higher than 400 MHz. FIG. 3 shows a frequency comparison result 108 (fup0) for accelerating the clock signal that is generated when the oscillation frequency of the VCO 110 is lower than 400 MHz. Thus, the oscillation frequency of the VCO 110 is slowed or accelerated by the frequency comparison results 108, so that the oscillation frequency is controlled so as to be 400 MHz.

FIG. 2 is a timing chart illustrating a mechanism for generating a frequency comparison result for slowing the frequency that is generated when the oscillation frequency of the VCO 110 is higher than 400 MHz among the five pairs of the frequency comparison results 108. FIG. 2 shows one result (fdn0 signal) of the five frequency comparison results (fdn0, fdn1, fdn2, fdn3, fdn4). When the frequency of the clock signal is higher than 400 MHz, a single pulse of the serial data of 2.0 Gb/s is wider in width than ⅕ of the clock cycle Tclk. Therefore, a transition occurs in transition detection intervals A for fdn0. The transition detection intervals A for fdn0 include (1) the phase 0-1 interval of the clock signal (dn0) and (4) the phase 3-4 interval of the clock signal (up3). The transition detection intervals A for fdn0 are illustrated as hatched phase intervals. Transitions within such specific intervals are detected by the phase comparison results 106.

Here, the phase comparison results 106 are control signals for synchronizing the rising timing of the clock signals clk0, clk2, clk4, clk6, and clk8 of the 10-phase clock signals 102 with the transition timing of the serial data. The phase comparison results 106 are obtained from an exclusive-OR operation of judgment results of the serial data obtained at the rising timing of adjacent two clock signals of the 10-phase clock signals. Therefore, as shown in FIG. 2, a phase comparison result 106 corresponds to a data transition in a specific interval. Data transitions in the transition intervals for fdn0 can be expressed by four conditions including (1) occurrence of a transition in the phase 0-1 interval (dn0) of the clock signal, (2) no occurrence of a transition in the phase 1-2 interval (up1) of the clock signal, (3) no occurrence of a transition in the phase 2-3 interval (dn2) of the clock signal, and (4) occurrence of a transition in the phase 3-4 interval (up3) of the clock signal. In other words, the frequency comparison result fdn0 can be generated by a logical operation of Formula (1) where * indicates an AND operation and ˜ indicates a NOT operation.

fdn0=dn0*˜up1*˜dn2*up3 (Formula 1)

FIG. 3 is a timing chart illustrating a mechanism for generating a frequency comparison result for accelerating the frequency that is generated when the oscillation frequency of the VCO 110 is lower than 400 MHz among the five pairs of the frequency comparison results 108 generated in the first embodiment. FIG. 3 shows one result (fup0 signal) of the five frequency comparison results (fup0, fup1, fup2, fup3, fup4). When the clock frequency is lower than 400 MHz, a single pulse of the serial data of 2.0 Gb/s is narrower in width than ⅕ of the clock cycle Tclk. Therefore, a transition occurs in transition detection intervals B for fup0. The transition detection intervals B for fup0 can be expressed by two conditions including (1) occurrence of a transition in the phase 1-2 interval (up1) of the clock signal and (2) occurrence of a transition in the phase 2-3 interval (dn2) of the clock signal. In other words, the frequency comparison result fup0 can be generated by a logical operation of Formula (2). Similarly, other four pairs of frequency comparison results can be generated by detecting a transition in a specific interval with use of the phase comparison results 106. In other words, the frequency comparison results 108 can be expressed by the following logical operations of Formula (2-10) where * indicates an AND operation and ˜ indicates a NOT operation using the phase comparison results 106.

fup0=up1*dn2 (Formula 2)

fdn1=dn2*˜up3*˜dn4*up5 (Formula 3)

fup1=up3*dn4 (Formula 4)

fdn2=dn4*˜up5*˜dn6*up7 (Formula 5)

fup2=up5*dn6 (Formula 6)

fdn3=dn6*˜up7*˜dn8* up9 (Formula 7)

fup3=up7*dn8 (Formula 8)

fdn4=dn8*˜up9*˜dn0*up1 (Formula 9)

fup4=up9*dn0 (Formula 10)

The frequency regeneration circuit of this embodiment oversamples the serial data (2 Gb/s) twice with the 10-phase clock signals for thereby regenerating a clock signal having a frequency corresponding to ⅕ of the frequency of the serial data. The serial data are first sampled by the judgment circuits provided within the phase comparator circuit, which operate with the 10-phase clock signals. Thus, the serial data are converted into judgment results as digital data. Phase comparison results generated from the judgment results are inputted to the frequency comparison logic. The frequency comparison logic performs a logical operation therein with use of the phase comparison results to thereby generate and output frequency comparison results. The charge pumps control the oscillation frequency of the VCO with use of the frequency comparison results. Thus, the frequency of the clock signal can be regenerated.

As described above, the width of a single pulse of the serial data is compared with the time width defined by a phase difference of multiphase clock signals. The frequency comparison logic calibrates the phase comparison results with the data transition interval having a width of a single pulse of the serial data to thereby obtain frequency comparison results. In order to regenerate a clock frequency that is 1/n of a rate of the serial data (where n is a natural number; and n=5 in the present embodiment), a frequency comparison result fdn for lowering the frequency is generated when the clock signal has a frequency higher than the 1/n clock frequency. A frequency comparison result fup for increasing the frequency is generated when the clock signal has a frequency lower than the 1/n clock frequency. The oscillation frequency of the VCO is controlled with use of the frequency comparison results so as to regenerate a frequency that is 1/n of the frequency of the clock signal.

(Second Embodiment)

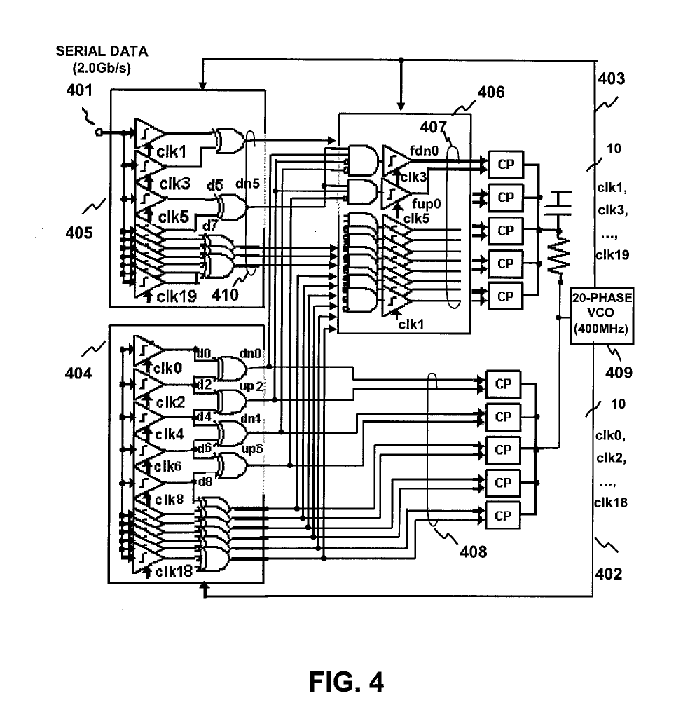

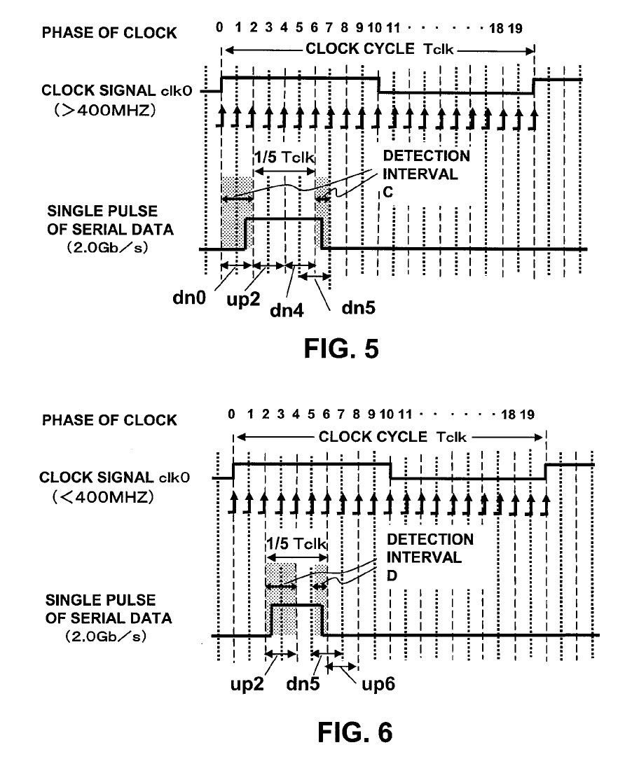

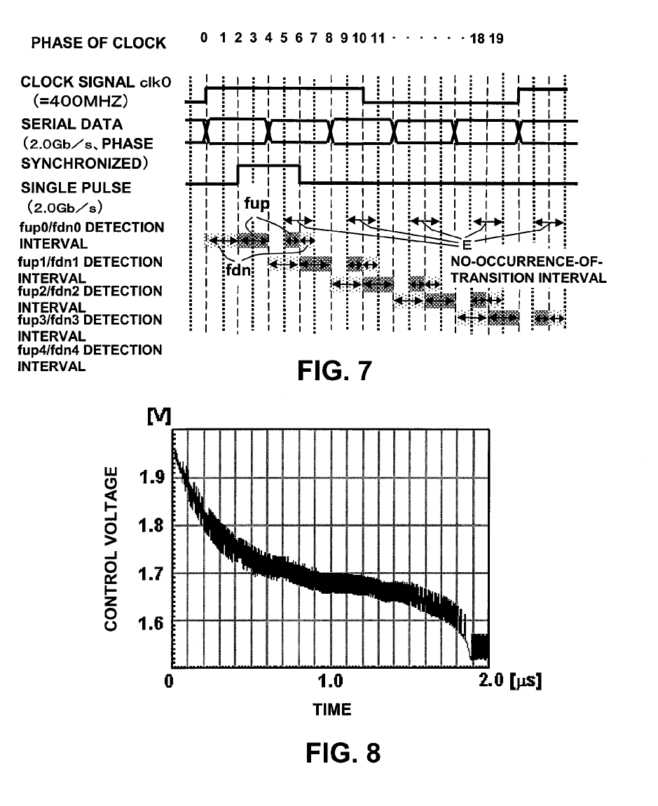

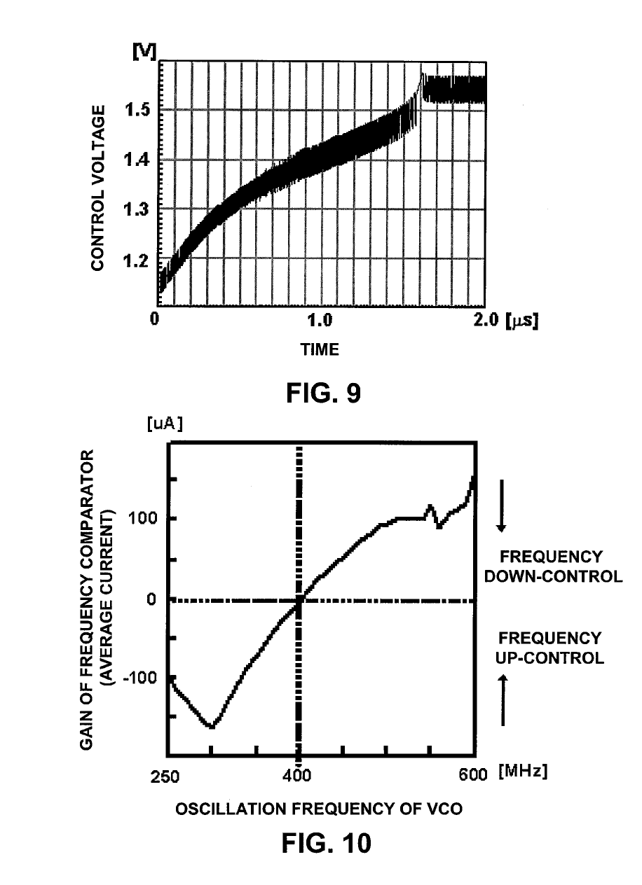

A second embodiment of the present invention will be described with reference to the drawings. FIG. 4 is a block diagram showing a frequency regeneration circuit according to a second embodiment of the present invention. FIG. 5 is a timing chart of generating a frequency comparison result (fdn0) in the second embodiment of the present invention, and FIG. 6 is a timing chart of generating a frequency comparison result (fup0). FIG. 7 is a timing chart showing a frequency comparison operation at the time of phase synchronization in the second embodiment of the present invention. FIGS. 8 and 9 show examples of a VCO control voltage when a frequency is regenerated in the second embodiment of the present invention. FIG. 10 shows an example of a frequency control gain in the second embodiment of the present invention. The frequency regeneration circuit shown in FIG. 4 includes phase comparator circuits 404 and 405, a frequency comparison logic 406, and a VCO 409. Serial data 401 of 2.0 Gb/s are oversampled four times with 20-phase clock signals including two lines of 10-phase clock signals 402 and 403 for thereby obtaining frequency comparison results 407 for a clock frequency of 400 MHz. The 20-phase clock signals include 20 phases of clock signals having adjacent phase differences clk0, clk1, . . . , clk19. For example, the clock signals clk1, clk3, . . . , clk19 with odd numbers among those 20-phase clock signals are supplied to the phase comparator circuit 405 and the frequency comparison logic 406. The clock signals clk0, clk2, . . . , clk18 with even numbers are supplied to the phase comparator circuit 404. Thus, the 10-phase clock signals of 20 phases with odd numbers and even numbers are supplied to the separate phase comparator circuits 404 and 405. Therefore, in the 10-phase clock signals supplied to the respective phase comparator circuits, for example, the clock signals clk0 and clk2 are clock signals having adjacent phase differences.

The present embodiment is provided with a phase control that is implemented with phase comparison results 408 outputted from the phase comparator circuit 404, in addition to a frequency control that is implemented with the phase comparator circuits 404 and 405 and the frequency comparison logic 406. A phase comparison control is performed when an oscillation frequency of the VCO 409 is brought sufficiently close to 400 MHz by a frequency control using the frequency comparison results 407. Thus, the data input 401 and the 10-phase clock signals 402 are synchronized in phase with each other.

The serial data 401 of 2.0 Gb/s are sampled at the phase comparator circuit 405 with the 10-phase clock signals 403 (clk1, clk3, . . . , clk19) and converted into judgment results (d1, d3, . . . , d19). Two judgment results sampled with adjacent phases of the 10-phase clock signals 403 (clk1-c1k19) are inputted to each of exclusive-OR circuits, which outputs a phase comparison result 410 to the frequency comparison logic 406. The judgment results sampled with adjacent phases (d1 and d3, d5 and d7, . . . , d17 and d19) are inputted to the exclusive-OR circuits of the phase comparator circuit 405. Each of the exclusive-OR circuits outputs a phase comparison result.

Similarly, the phase comparator circuit 404 samples the serial data 401 being inputted with the 10-phase clock signals 402 (clk0, clk2, . . . , clk18) and converts them into judgment results (d0, d2, . . . , d18). Two judgment results sampled with adjacent phases of the 10-phase clock signals 403 (c1k0-clk18) are inputted to each of exclusive-OR circuits, which outputs a phase comparison result 410 to the frequency comparison logic 406. The judgment results sampled with adjacent phases (d0 and d2, d2 and d4, . . . , d18 and d0) are inputted to the exclusive-OR circuits of the phase comparator circuit 404. Each of the exclusive-OR circuits outputs a phase comparison result.

The frequency comparison logic 406 performs a logical operation therein with use of the inputted phase comparison results 408 and 410 to thereby generate and output frequency comparison results 407. The frequency comparison logic 406 outputs five pairs of frequency comparison results 407 (fdn0 and fup0), (fdn1 and fup1), . . . , (fdn4 and fup4), which are synchronized with the clock signal. Charge pumps, to which those five pairs of frequency comparison results 407 are inputted, control an oscillation frequency of the VCO 409. A frequency control is interrupted when an oscillation frequency of the VCO 409 is brought sufficiently close to 400 MHz by a frequency control using the frequency comparison results 407. In this case, the charge pumps are controlled with use of the phase comparison results 408 outputted from the phase comparator circuit 404. Thus, a phase comparison control of the VCO 409 is performed, and the data input 401 and the 10-phase clock signals 402 are synchronized in phase with each other.

In the second embodiment of the present invention, as with the first embodiment, whether or not a single pulse of the serial data 401 make a transition in a specific interval is detected based upon the phase comparison results 408 and 410 in order to generate frequency comparison results 407. FIGS. 5 and 6 are timing charts of generating a frequency comparison result fdn0 and a frequency comparison result fup0. The frequency comparison result fdn0 is generated from data transition intervals including transition detection intervals C for fdn0 by a logical operation of Formula 11. The frequency comparison result fup0 is generated from data transition intervals including transition detection intervals D for fup0 by a logical operation of Formula 12. Similarly, other four sets of frequency comparison results are generated by logical operations of the following Formulas where * indicates an AND operation and ˜ indicates a NOT operation.

fdn0=dn0*˜up2*˜dn4*dn5 (Formula 11)

fup0=up2*dn5*˜up6 (Formula 12)

fdn1=dn4*˜up6*˜dn8*dn9 (Formula 13)

fup1=up6*dn9*˜up10 (Formula 14)

fdn2=dn8*˜up10*˜dn12*dn13 (Formula 15)

fup2=up10*dn13*˜up14 (Formula 16)

fdn2=dn12*˜up14*˜dn16*dn17 (Formula 17)

fup2=up14*dn17*˜up18 (Formula 18)

fdn2=dn16*˜up18*˜dn0*dn1 (Formula 19)

fup2=up18*dn1*˜up2 (Formula 20)

FIG. 7 is a timing chart at the time when an oscillation frequency of the VCO 409 is equal to 400 MHz. With a phase control in the second embodiment, the rising timing of the 10-phase clock signals 402 (clk0, clk4, clk8, clk12, clk16) is synchronized with transitions of the serial data 401. One of features of such a timing relationship between the clock signals and the data is that no transition of data occurs in no-occurrence-of-transition intervals E between dotted lines of FIG. 7, which are indicated by arrows. In other words, no transition of data occurs in fup/fdn detection intervals, which are required to generate the frequency comparison results 407. As to the fdn0/fup0 detection intervals, a transition of data may occur in the phase 0-4 interval of the clock signal because of a timing shift between the serial data and the clock signals. A probability of a transition of data is sufficiently low in the phase 5-7 interval of the clock signal. With such a configuration, it is possible to suppress outputs of the frequency comparison results in a state in which a phase synchronization has been performed.

FIGS. 8 and 9 show examples of variations of a control voltage for the VCO 409 that was obtained when a frequency was regenerated with use of the second embodiment. It can be seen that a phase synchronization was performed after a frequency synchronization around 1.55 V when a frequency was regenerated in a case where an initial frequency of the VCO 409 was higher than 400 MHz (FIG. 8), or when a frequency was regenerated in a case where an initial frequency of the VCO 409 was lower than 400 MHz (FIG. 9). FIG. 10 is an example of a graph in which a frequency control gain of the frequency regeneration circuit according to the second embodiment of the present invention is represented by an average current outputted from the charge pumps. The polarity of the current is reversed at 400 MHz. When the clock frequency is higher than 400 MHz, a control for lowering the frequency is performed. When the clock frequency is lower than 400 MHz, a control for increasing the frequency is performed.

In the present embodiment, serial data of 2.0 Gb/s are oversampled four times with 20-phase clock signals including two lines of 10-phase clock signals. Thus, frequency comparison results are obtained for a clock frequency of 400 MHz. Phase comparison results are generated from judgment results in which the serial data have been sampled with the corresponding 10-phase clock signals by using two phase comparator circuits. The frequency comparison logic generates frequency comparison results from the phase comparison results and controls an oscillation frequency of the VCO. In addition to such a frequency control, a phase comparison control is performed when an oscillation frequency of the VCO is brought sufficiently close to 400 MHz. Thus, the serial data input and the 10-phase clock signals can be synchronized in phase with each other.

(Third Embodiment)

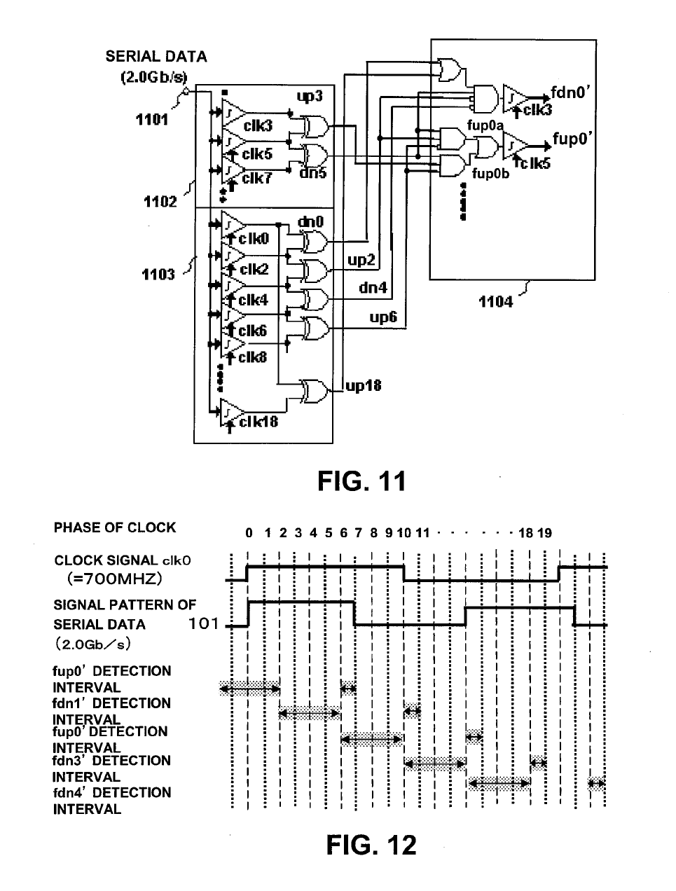

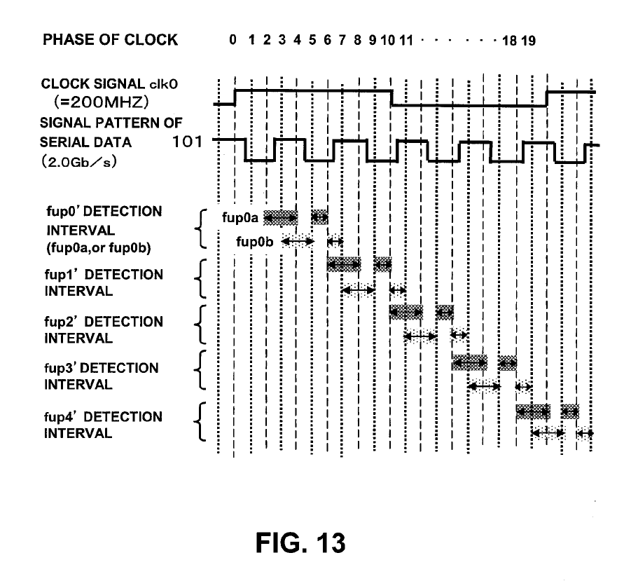

A third embodiment of the present invention will be described with reference to the drawings. FIG. 11 is a block diagram showing phase comparator circuits 1102 and 1103 and a frequency comparison logic 1104 within a frequency regeneration circuit according to the present embodiment. FIG. 12 is a timing chart showing transition detection intervals for generating five frequency comparison results (fdn0′, fdn1′, fdn2′, fdn3′, fdn4′) in a frequency regeneration circuit according to the present embodiment when a clock frequency is higher than 400 MHz. FIG. 13 is a timing chart showing transition detection intervals for generating five frequency comparison results (fup0′, fup1′, fup2′, fup3′, fup4′) when a clock frequency is lower than 400 MHz.

FIG. 11 is a partial block diagram of the interior of the frequency regeneration circuit according to the present embodiment and shows the phase comparator circuits 1102 and 1103 and the frequency comparison logic 1104. FIG. 11 partially illustrates the interior of the frequency regeneration circuit. As with the previous embodiment, 20-phase clock signals including lines of 10-phase clock signals are supplied to the charge pumps, the VCO, and the phase comparator circuits 1102 and 1103.

The phase comparator circuit 1102 samples serial data 1101 of 2.0 Gb/s with the 10-phase clock signals (clk1, clk3, . . . , clk19) among the 20-phase clock signals to thereby obtain judgment results. Phase comparison results (dn1, up3, dn5, . . . , up19) are outputted to the frequency comparison logic 1104 with use of judgment results that have been sampled with adjacent phases. The phase comparator circuit 1103 samples the serial data 1101 of 2.0 Gb/s with the 10-phase clock signals (clk0, clk2, . . . , clk18) and outputs phase comparison results (dn0, up2, dn4, . . . , up18) to the frequency comparison logic 1104 with use of signals that have been sampled with adjacent phases.

The frequency comparison logic 1104 generates frequency comparison results based upon the phase comparison results inputted from the phase comparator circuits 1102 and 1103. For example, the phase comparison results dn0 and up18 are inputted to an OR circuit. An output from the OR circuit, the phase comparison result dn5, the negative of the phase comparison result up2, and the negative of the phase comparison result dn4 are inputted to an AND circuit, which outputs a frequency comparison result fdn0′ that is synchronized with the clock signal clk3. Furthermore, the phase comparison results dn5 and up2 and the negative of the phase comparison result up6 are inputted to an AND circuit, and the phase comparison results dn5 and up3 and the negative of the phase comparison result up6 are inputted to an AND circuit. Outputs of those AND circuits (fup0a, fup0b) are inputted to an OR circuit, which outputs a frequency comparison result fup0′ that is synchronized with the clock signal clk5. Transition detection intervals for generating those frequency comparison results are illustrated in FIG. 12, which shows the case where a clock frequency is higher than 400 MHz, and in FIG. 13, which shows the case where a clock frequency is lower than 400 MHz.

The frequency regeneration circuit of the present embodiment shown in FIG. 11 can widen the operation frequency as compared to the second embodiment. The upper limit of the operation frequency of the frequency regeneration circuit according to the second embodiment is 700 MHz, which is 7/4 of the target frequency of 400 MHz. This can be calculated from the widest single pulse that passes through the transition detection intervals for fdn0 shown in FIG. 5. The frequency regeneration circuit of the third embodiment widens transition detection intervals as shown in FIG. 12, so that a correct frequency comparison result can be outputted from 900 MHz, which is 9/4 of the target frequency to 400 MHz.

Meanwhile, FIG. 13 shows transition detection intervals for generating five frequency comparison results when a clock frequency is lower than 400 MHz. FIG. 13 also shows the timing relationship between transition detection intervals and serial data (2.0 Gb/s), which is obtained by the 20-phase clock signals (200 MHz). The lower limit of the operation frequency of the frequency regeneration circuit according to the second embodiment is 200 MHz with respect to the target frequency of 400 MHz. This is because no transition of the serial data occurs in any of the five transition detection intervals (fup0, fup1, fup2, fup3, fup4).

In the frequency regeneration circuit according to the third embodiment, detection intervals are added to the detection intervals used in the second embodiment. Thus, a frequency comparison can be made at a frequency of 200 MHz or less. The frequency comparison logic of FIG. 13 has two AND circuits, each of which outputs frequency comparison results fup0a and fup0b. An OR operation of frequency comparison results fup0a and fup0b generates a frequency comparison result fup0′. Therefore, when a transition is detected by either the frequency comparison result fup0a or fup0b, the frequency comparison result fup0′ is outputted. The fup0-fup4 detection interval in the second embodiment corresponds to fup0a-fup4a. A frequency comparison can be made in a wide range by addition of the detection intervals fup0b-fup4b.

In the present embodiment, serial data of 2.0 Gb/s are oversampled with 20-phase clock signals including two lines of 10-phase clock signals. Thus, frequency comparison results are obtained for a clock frequency of 400 MHz. Phase comparison results are generated from judgment results in which serial data have been sampled with the corresponding 10-phase clock signals by using two phase comparator circuits. The logical configuration of the frequency comparison logic is changed and added to widen the transition detection intervals. Thus, a correct frequency comparison result is outputted from a wide frequency region, and an oscillation frequency of the VCO can be controlled.

A frequency regeneration circuit according to the present invention oversamples serial data with multi-phase clock signals for thereby generating a clock signal corresponding to 1/n of a frequency of the serial data (where n is a natural number). The serial data are first sampled by a judgment circuit provided within a phase comparator circuit, which is operable with multi-phase clock signals, and converted into judgment results as digital data. Phase comparison results generated from the judgment results are inputted to a frequency comparison logic. The frequency comparison logic performs a logical operation so that the phase comparison results are calibrated with data transition intervals having a width of a single pulse of the serial data. Thus, frequency comparison results are generated. With use of those frequency comparison results, charge pumps can control an oscillation frequency of the VCO and regenerate a frequency of the clock signal.

In a frequency regeneration circuit according to the present invention, the width of a single pulse of serial data being inputted can be compared with a phase difference of multi-phase clock signals by detecting consecutive transitions of the input data in two different periods of time defined by the multi-phase clock signals. The detection of transitions can be made by performing a logical operation on judgment results obtained from a judgment circuit that operates upon rising edges of the multi-phase clock signals.

Furthermore, the judgment with the multi-phase clock signals to detect a transition is made at a rate that is at least twice a rate of the input data. When the judgment with the multi-phase clock signals is made at a rate that is four times a rate of the input data, detection of a frequency difference can be interrupted in a state in which the multi-phase clock signals are synchronized in phase with the input data. Additionally, a transition with the multi-phase clock signals is detected with use of phase comparison results obtained from judgment results of the multi-phase clock signals by exclusive-OR circuits. A logical operation of the phase comparison results can be performed with a synchronization circuit using the clock signal.

According to the present invention, there can be provided a frequency regeneration circuit that can regenerate a clock signal by comparing a width of a single pulse of input data with a time width of a clock cycle defined by a phase difference of multi-phase clock signals and by performing a logical operation. Thus, there can be provided a frequency regeneration circuit that can regenerate a frequency that is 1/n of input data (where n is a natural number) with use of judgment results obtained from judgment of the input data and a synchronization circuit without an analog amplifier circuit for amplifying the serial data.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

Description of Reference Numerals

101, 401, 1101 serial data

102, 402, 403 10-phase clock signal

103, 404, 405, 1102, 1103 phase comparator circuit

104 judgment circuit

105 judgment result

106, 408, 410 phase comparison result

107, 406, 1104 frequency comparison logic

108, 407 frequency comparison result

109 charge pump

110, 409 VCO

1. A frequency regeneration circuit, comprising: comparing a width of a single pulse of input data with a time width of a 1/n clock cycle defined by a phase difference of multi-phase clock signals (where n is a natural number) in order to regenerate a frequency that is 1/n of a rate of the input data.

2. The frequency regeneration circuit according to claim 1, wherein the frequency regeneration circuit detects consecutive transitions of the input data in two difference periods of time defined by the multi-phase clock signals in order to compare the width of the single pulse of the input data with the phase difference of the multi-phase clock signals.

3. The frequency regeneration circuit according to claim 2, wherein the detection of the transitions is made by performing a logical operation on judgment results obtained from a judgment circuit that operates upon rising edges of the multi-phase clock signals.

4. The frequency regeneration circuit according to claim 3, wherein the judgment of the multi-phase clock signals to detect the transitions is performed at a rate that is at least twice a rate of the input data.

5. The frequency regeneration circuit according to claim 4, wherein the judgment of the multi-phase clock signals is performed at a rate that is four times a rate of the input data for thereby interrupting a detection of a frequency difference in a state in which the multi-phase clock signals are synchronized in phase with the input data.

6. The frequency regeneration circuit according to claim 4, wherein the detection of the transitions with use of the multi-phase clock signals is performed with use of phase comparison results obtained by an exclusive-OR operation of the judgment results of the multi-phase clock signals.

7. The frequency regeneration circuit according to claim 4, wherein the logical operation on the judgment results is performed by a synchronization circuit using the clock signal.

8. A frequency regeneration circuit, comprising:
a judgment circuit operable to sample input data with multi-phase clock signals to obtain judgment results;
an exclusive-OR circuit operable to compare judgment results that have been sampled with clock signals having adjacent phase differences to each other for thereby outputting phase comparison results;
a frequency comparison logic operable to output frequency comparison results in which a logical operation has been performed on the phase comparison results;
a charge pump circuit operable to output a control voltage, the frequency comparison results being inputted to the charge pump circuit; and
a voltage controlled oscillator controlled by the control voltage so as to output multi-phase clock signals having a frequency that is 1/n of a rate of the input data (where n is a natural number).

9. A frequency regeneration method, including:
converting input data into judgment results that have been sampled with multi-phase clock signals each having a certain phase difference;
obtaining phase comparison results by an exclusive-OR operation on the judgment results that have been sampled with clock signals having adjacent phase differences;
outputting frequency comparison results obtained by performing a logical operation on the phase comparison results; and
outputting multi-phase clock signals controlled by the frequency comparison results, the multi-phase clock signals having a frequency that is 1/n of a rate of the input data where n is a natural number.
